(19) United States
(12) Patent Application Publication
(10) Pub. No.: US 2025/0132341 A1
(43) Pub. Date: Apr. 24, 2025

(54) Aqueous-Based High Nickel Electrodes Manufacturing Using Sustainable Cellulose Nanomaterials as Protector

(71) Applicant: Northeastern University, Boston, MA (US)

(72) Inventors: Hongli Zhu, Newton, MA (US); Ying Wang, Boston, MA (US)

(21) Appl. No.: 18/759,795

(22) Filed: Jun. 28, 2024

Related U.S. Application Data
(60) Provisional application No. 63/510,984, filed on Jun. 29, 2023.

(51) Int. Cl. H01M 4/62; C30B 29/22; H01M 4/02; H01M 4/131; H01M 4/1391; H01M 4/525; H01M 10/0525

(52) U.S. Cl. CPC H01M 4/622; C30B 29/22; H01M 4/131; H01M 4/1391; H01M 4/525; H01M 4/625; H01M 10/0525; H01M 2004/028

(57) ABSTRACT

Provided herein, in various embodiments, are methods for making a water-stable electrode by combining a mixture of cellulose nanofibers (CNF) and cellulose nanocrystals (CNC). Also described in embodiments herein are water-stables electrode comprising a mixture of CNF and CNC as a hybrid binder. Also described herein are batteries and devices. Also described herein are methods of protecting an electrode in water from delithiation.

### RELATED APPLICATION(S)

This application claims the benefit of U.S. Provisional Application No. 63/510,984, filed on Jun. 29, 2023. The entire teachings of the above application are incorporated herein by reference.

### GOVERNMENT SUPPORT

This invention was made with government support under Grant Number DE-EE0009111 awarded by the U.S. Department of Energy. The government has certain rights in the invention.

### BACKGROUND

LiNi_{1-x-y}CoₓMn_{y}O₂ (NMC) electrodes are hailed as the “near-future” cathode for lithium-ion battery (LIB) manufacturing. However, NMC particles are highly humidity-sensitive materials and cannot be fabricated with water as a solvent. Adding phosphoric acid and introducing metal oxides are previously available approaches to realize water-based processing. Nevertheless, the current electrochemical performances of aqueous-based NMC electrodes are not comparable to those of N-methyl-2-pyrrolidone (NMP)-based NMC electrodes, which hinders the industrialization of aqueous-based NMC processing.

### SUMMARY

Described herein, in some embodiments, is a method for making a water-stable electrode by combining a mixture of cellulose nanofibers (CNF) and cellulose nanocrystals (CNC), as a hybrid binder, active materials, and conductive material into an evenly mixed slurry in a solvent; and drying the slurry to form an electrode.

In some embodiments, the active materials comprise lithium, nickel, cobalt, manganese, oxygen, or any combination thereof. In other embodiments, the active materials are a single crystal in a ratio of LiNi_{1-x-y}CoₓMn_{y}O₂. In other embodiments, the single crystal is LiNi_{0.8}Co_{0.1}Mn_{0.1}O₂ (NMC 811).

In some embodiments, the CNF is prepared using a chemical oxidation reaction. In other embodiments, the CNF preparation is performed using 2,2,6,6-tetramethylpiperidine-1-oxyl (TEMPO) oxidation.

In some embodiments, the active materials, conductive material, and hybrid binder are combined such that the active materials comprise the largest weight percentage, the conductive material comprises the second largest weight percentage, and the hybrid binder comprises the third largest weight percentage. In other embodiments, the weight percentages of active materials, conductive material, and hybrid binder are about 85:10:5. In other embodiments, the weight percentage of active materials, conductive material, and hybrid binder are about 90:6:4. In other embodiments, the weight percentage of active materials, conductive material, and hybrid binder are about 92:5:3.

In some embodiments, the conductive material is carbon black (e.g., Super P). In other embodiments, the hybrid binder is dissolved in the solvent before the active materials and the carbon black.

In some embodiments, the hybrid binder comprises a mass ratio of CNC to CNF of a range of about 100:0 to about 0:100. In other embodiments, the hybrid binder comprises a mass ratio of CNC to CNF of a range of about 75:25 to about 25:75. In other embodiments, the hybrid binder comprises a mass ratio of CNC to CNF of about 1:1.

In some embodiments, the solvent is water. In other embodiments, the solvent is a dry solvent or an organic solvent.

In some embodiments, the solvent is organic solvent.

Also described herein is a water-stable electrode comprising a mixture of CNF and CNC as a hybrid binder, active materials, and conductive material. In some embodiments, the active materials of the electrode comprise lithium, nickel, cobalt, manganese, oxygen, or any combination thereof. In other embodiments, the active materials are in a single crystal in a ratio of LiNi_{1-x-y}CoₓMn_{y}O₂. In other embodiments, the single crystal is LiNi_{0.8}Co_{0.1}Mn_{0.1}O₂ (NMC 811).

In some embodiments, the hybrid binder of the water-stable electrode comprises a mass ratio of CNC to CNF of a range of about 100:0 to about 0:100. In other embodiments, the hybrid binder comprises a mass ratio of CNC to CNF of a range of about 75:25 to about 25:75. In other embodiments, the hybrid binder comprises a mass ratio of CNC to CNF of about 1:1.

In some embodiments, the hybrid binder of the water-stable electrode prevents delithiation of the active materials in water. In other embodiments, the hybrid binder captures water molecules, conducts lithium ions, or captures water molecules and conducts lithium ions.

In some embodiments, the water-stable electrode exhibits an initial coulombic efficiency of at least 70%. In other embodiments, the water-stable electrode exhibits an initial coulombic efficiency of at least 80%. In other embodiments, the water-stable electrode exhibits an initial coulombic efficiency of at least 85%.

In some embodiments, the conductive material is carbon black (e.g., Super P).

Also described herein is a battery comprising a cathode, an anode, an electrolyte, and a current collector, wherein at least the cathode is the water-stable electrode described herein. In other embodiments, the hybrid binder of the water-stable electrode in the battery has a mass ratio of CNC to CNF of about 100:0 to about 0:100. In other embodiments, the hybrid binder comprises a mass ratio of CNC to CNF of a range of about 75:25 to about 25:75. In other embodiments, the hybrid binder comprises a mass ratio of CNC to CNF of about 1:1.

In some embodiments, the battery is used in, or is part of, a device, such as an electronic device, an electric vehicle, a portable high-energy density power source, a consumer electronic, energy grid storage, or a medical device. Also described herein, is a device, e.g., an electronic device or medical device, comprising a battery described herein.

Also described herein is a method of protecting an electrode in water from delithiation, the method comprising applying a protective layer to the electrode through a homogenous slurry in a solvent that captures water and allows the pass through of lithium ions. In other embodiments, the homogenous slurry of the method comprises a hybrid binder, active materials and conductive material that is dried to form a protective layer on the electrode. In other embodiments, the hybrid binder comprises CNF, CNC, or a combination of CNF and CNC. In other embodiments, the combination of CNF and CNC is in a mass ratio of about 100:0 to about 0:100. In other embodiments, the combination of CNF and CNC is in a mass ratio of about 75:25 to about 25:75. In other embodiments, the combination of CNF and CNC is in a mass ratio of about 1:1.

In some embodiments, the active materials of the electrode protective layer comprise lithium, nickel, cobalt, manganese, oxygen, or any combination thereof. In other embodiments, the active materials are in a single crystal in a ratio of LiNi_{1-x-y}CoₓMn_{y}O₂. In other embodiments, the single crystal is LiNi_{0.8}Co_{0.1}Mn_{0.1}O₂ (NMC 811). In some embodiments, the conductive material of the protective layer is carbon black (e.g., Super P). In some embodiments, the active materials are that of an anode.

In some embodiments, water is used in place of organic solvent for electrode manufacturing. In other embodiments, the use of water realizes inexpensive, non-toxic, and/or eco-friendly control in NMC electrode manufacturing. Example embodiments described herein utilize sustainable, biodegradable, earth-plentiful, and/or cheap cellulose nanomaterials as a binder. Using example embodiments described herein, preparation processes of raw materials for embodiments are simplified compared to previous methods.

In other non-limiting embodiments, optimized aqueous-based NMC electrodes exhibit comparable charge capacities to NMP-based NMC electrodes at all current rates. Further, the optimized aqueous-based NMC electrode displays improved cycling stability compared to the NMP-based NMC electrode.

In some embodiments, cellulose nanomaterials are used as a component in an electrode rather than an additive. The cellulose nanomaterials are biodegradable, which reduces the difficulty of recycling batteries. In other embodiments, NMC electrodes with cellulose nanomaterials binders exhibit a higher (e.g., much higher) rate performance and cycling stability compared to other aqueous-based NMC electrodes.

Also described herein, in some embodiments, are methods of stabilizing nickel-rich cathodes in aqueous process via nanochannel water confinement.

In other non-limiting embodiments, embodiments described herein may be used in technology that may include, but is not limited to, portable high-energy density power sources, such as electric vehicles, consumer electronics, aerospace and defense, energy grid storage, and/or medical devices.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIGS. 1A-1C are schematics of (FIG. 1A) a reaction between NMC particles and water, (FIG. 1B) a mechanism of the cellulose nanomaterials coverage on NMC particles, and (FIG. 1C) a mechanism of CNC-CNF coverage blocking water entry but allowing Li-ion transfer.

FIGS. 2A-2C are schematics of coverages composed of (FIG. 2A) CNC, (FIG. 2B) CNF, and (FIG. 2C) CNC-CNF in the aqueous-based system. With the number of nanomaterials, the rod-like CNC lack connection with each other, and it is difficult to form a uniform protection film. Different from the CNC, CNF is long enough to be stacked on each other and generate an excellent film to limit water molecules while maintaining some uncovered regions. Superior to using only CNF, the CNC introduction assists in filling the small gaps between the randomly stacked fibers and creating a denser coverage.

FIGS. 3A-3F are interactions between nanocellulose and water. (FIG. 3A) The CNC and CNF were derived from trees. (FIG. 3B) The structures of CNC and CNF were affected by various processes. (FIGS. 3C and 3D) WAXS patterns of wet and dry CNC and CNF. (FIGS. 3E and 3F) Schematics of cellulose channels and water molecules capture in unoxidized and oxidized celluloses.

FIG. 4 is a depiction of a simulation of a cellulose chain.

FIG. 5 is multiple SEM images of single crystalline NMC 811 particles.

FIGS. 6A-6F Nanocelluloses coating on NMC particles. (FIGS. 6A-D) SEM micrographs of CMC-SBR electrode, CNC electrode, CNF electrode, and CNC-CNF electrode at various magnifications. (FIG. 6E) Zeta potential of NMC particles and nanocelluloses in aqueous solution. (FIG. 6F) Schematic of CNC-CNF coverage formation on NMC 811 particles.

FIG. 7 highlights the surface of the CNC-CNF electrode. A dense and thin layer of coating was covered on the NMC, in which a tiny gaping hole shows the wrapped NMC particle. Yellow is carbon black, and purple is the exposed area of the NMC particle.

FIG. 8 is a digital image of 0.05 wt. % NMC particles and cellulose nanomaterials dispersed into water.

FIGS. 9A-9D Electrochemical performance of NMC 811 aqueous-processed electrodes. (FIG. 9A) Galvanostatic charge-discharge curves of CNC-CNF (solid line) and CMC-SBR (dash line) electrodes at the current rate of 0.1 C. (FIGS. 9B-D) Nyquist plots, rate performance, and cycling stability of aqueous-based NMC 811 electrodes using CNC-CNF and CMC-SBR as a binder.

FIGS. 10A-10C are Nyquist plots and fitting results of (FIG. 10A) CNC-CNF and (FIG. 10B) CMC-SBR electrodes. FIG. 10C is a schematic of an equivalent circuit used for electrochemical impedance spectroscopy (EIS).

FIGS. 11A-11B (FIG. 11A) Rate performance and (FIG. 111B) cycling stability of aqueous-based electrodes covered using various CNC and CNF ratios.

FIGS. 12A-12F Electrochemical performance comparison of acid included CNC-CNF electrodes. (FIG. 12A) Schematics of the role sulfuric acid plays in CNC synthesizing procedure and protect current collector of NMC electrode. (FIG. 12B) SEM images of the H⁺-CNC-CNF current collector removed electrode materials. (FIG. 12C) Galvanostatic charge-discharge curves of CNC-CNF (solid lines) and H⁺ CNC-CNF (dash line) electrodes at a charge rate of 0.1 C. (FIG. 12D-12F) Nyquist plots, rate performance, and cycling stability of the aqueous-based NMC 811 electrodes with nanocellulose binders and the NMP-based electrode with PVDF binder.

FIG. 13 SEM image of the CMC-SBR current collector removed electrode materials.

FIG. 14 Plot of resistance versus distance of CMC-SBR and H⁺ CNC-CNF current collectors.

FIG. 15 XRD results of NMC 811 particles pretreated using different binders in water. The X-ray energy is 8.0 keV.

FIG. 16A and FIG. 16B are digital images of disassembled H⁺ CNC-CNF and PVDF electrodes after testing.

FIGS. 17A-17D (FIG. 17A) Galvanostatic charge-discharge curves (FIG. 17B) Nyquist plots, (FIG. 17C) rate performance, and (FIG. 17D) cycling stability of H⁺ CNC and CNC electrodes. Acid modification is necessary for the electrodes using pure CNC as a binder.

FIGS. 18A-18B (FIG. 18A) Rate performance and (FIG. 18B) cycling stability of aqueous-based electrodes covered using various H⁺ CNC and CNF ratios.

FIG. 19 is a comparison of aqueous-based NMC electrodes using binders at a current rate of 1 C.

FIGS. 20A-20C Digital images of (FIG. 20A) H⁺ CNC-CNF mixture, (FIG. 20B) NMC electrode slurry with H⁺ CNC-CNF binder, and (FIG. 20C) a screen-printed electrode on the Al current collector.

FIG. 21 is multiple SEM images of screen-printed electrodes with some designed pores.

FIGS. 22A-22D depict simulation results. (FIG. 22A) Atomic structure of H₂O, CH₃COO, HSO₃ groups adsorbed on NMC surface. (FIG. 22B) Delithiated NMC electrode with Li⁺ moving from the subsurface to the surface 3b sites of NMC surface under H₂O, —R—COO, —HSO₃ adsorption. (FIG. 22C) Atomic structure of two parallel cellulose chains. (FIG. 22D) Snapshot of two layers of cellulose interacting with water obtained from an NVT MD simulation at 600K.

FIGS. 23A-23E are snapshots of water-cellulose structures from NVT MD simulations with polymer chains separated by 5 Å within each layer and various interlayer spacings: (FIG. 23A) 5 Å, (FIG. 23B) 10 Å, and (FIG. 23C) 15 Å. Top views of porous structures with polymer chains within each layer separated by (FIG. 23D) 5 Å, and (FIG. 23E) 15 Å.

### DETAILED DESCRIPTION

A description of example embodiments follows.

Water is preferable as a solvent in the electrode manufacturing industry because it is low-cost, nontoxic, and environmentally friendly. However, the manufacture of a water-based cathode (e.g., a LiNi_{1-x-y}CoₓMn_{y}O₂ (NMC) cathode) has not yet been industrialized on a large scale since the severe proton-lithium exchange causes the decomposition of corresponding materials and electrode capacity reduction. Through the mutual attraction from surface charges of materials, this work created an in situ protection layer for NMC particles using biodegradable and sustainable cellulose nanomaterials. This dense coverage can inhibit the diffusion of water molecules toward NMC particles and maintain the electrochemical performances of electrodes. At a charge current density of 6 C, the as-protected NMC electrode (158 mAh/g) delivered a higher capacity than the conventional NMC electrode (106 mAh/g) when subjected to aqueous processing. Furthermore, the protected aqueous-based NMC electrode demonstrated comparable rate performances and superior cycling stability to the N-methylpyrrolidone-based NMC electrode. This study enables highly efficient and affordable aqueous NMC electrode manufacturing.

Lithium-ion batteries (LIBs) are intensively being researched and developed to keep pace with the growing demand for electric vehicles and portable electronics. In order to achieve the goal of similar or even longer travel distance with the gasoline car for each charge, adequate energy density through developing high specific capacity materials is being investigated. Therefore, nickel-rich metal layered oxides, particularly the LiNi_{1-x-y}CoₓMn_{y}O₂ (NMC), are hailed as the “near-future” cathode materials by the automotive industry because of their high specific capacity.[1, 2] Despite the fact that nickel-rich materials possess a higher specific capacity compared to other commercial cathode materials, such as LiFePO₄ and LiCoO₂, they lack humidity stability, which inevitably leads to rising difficulties and costs in industrial manufacturing.[3, 4] The weak humidity stability of NMC particles results from proton exchange induced by the interaction between Lithium ions (Li⁺) and water molecules.[5] As the material exchanges protons, migrated Li⁺ reacts with atmospheric water and carbon dioxide to yield LiOH, LiHCO₃, and Li₂CO₃.[6] These reactions decompose the structure and degrade the electrochemical performances of NMC materials.[7, 8] Concurrently, associated products raise the pH of the slurry and corrode the Aluminum (Al) current collector.[9] Nevertheless, water is an environmentally friendly, cost-effective, and nontoxic solvent compared to its alternative, N-methyl-2-pyrrolidone (NMP) solvent, making industrial production of aqueous-based NMC electrodes a challenging but rewarding endeavor.[10]

NMC particles surface engineering and current collector protection are the two available methods to achieve aqueous-based NMC processing. [9, 11, 12] Introducing phosphoric acid is an efficient method to improve the electrochemical performances of aqueous-based NMC materials. The in situ generated protective layer of phosphate species limits further metal leaching of active materials and buffers the elevated pH to reduce erosion of the current collector.[11] Further investigations on pH modification [13] and binder selections [14-16] enhanced the rate performance and stability of aqueous-based NMC electrodes. Although aqueous-based NMC electrodes are progressively being optimized, their electrochemical performances are not comparable to those of NMP-based NMC electrodes, which impedes the industrialization of aqueous-based NMC processing.

Cellulose nanomaterials, including cellulose nanofibril (CNF) and cellulose nanocrystal (CNC), are sustainable, biodegradable, and earth plentiful biomass materials derived from wood.[17] CNF and CNC have been applied to LIBs extensively with different purposes. In specific, CNF possesses exceptional mechanical properties and has been widely employed as a binder in the aqueous-based LIBs production process, [18-20] while the rod-like CNC is often used as a reinforcing agent to improve mechanical properties of its filled or covered materials since its low density and high tensile strength.[21-24] Additionally, cellulose coating layers have outstanding water barrier properties that can minimize the continuous access of water to the covered materials.[25, 26] Unlike macromolecules of water, Li⁺ can rapidly transfer within cellulose molecular channels. The anticipated Li⁺ transfer kinetic aids electrodes to exhibit extraordinary Li⁺ conductivity in batteries.[27, 28]

Described herein are cellulose nanomaterials, e.g., wood-derived sustainable cellulose nanomaterials, as a binder for moisture-sensitive nickel-rich LIB cathode materials, single crystalline LiNi_{0.8}Co_{0.1}Mn_{0.1}O₂ (NMC 811), to implement aqueous-based processing, confine water penetration, mitigate environmental impact, reduce costs, and assure operational safety. The CNC-CNF hybrid binder provides a dense and tough protective coverage for NMC 811 particles in an aqueous environment, e.g., water, to prevent proton exchange because of water ingress during electrode production while permitting even accelerating Li⁺ transport during charging and discharging. The first principles density functional theory (DFT) calculations predict that the functional groups of CNC and CNF exhibit stronger binding strength with NMC particle surface than water molecules, and the tendency of Li⁺ moves to the NMC surface could be suppressed by the CNC and CNF coating. These results suggest that the rapid formation of protective cellulose coating covering NMC particles is possible, leading to a reduction in proton exchange during water processing. Consequently, NMC 811 electrodes composed of optimized CNC-CNF binder displayed a remarkable charge capacity, which was nearly three times higher at 6 C than that of the conventional electrode using CMC-SBR binder. Analysis of wide-angle X-ray scattering (WAXS) accurately measured the dimension of nanochannels within CNF and CNC, combines molecular dynamics (MD) simulation to understand the cellulose-water interactions, as well as proposes that the hydrophilic celluloses could effectively trap interlayer water into their nanochannels and, thus, prevent water from penetrating the NMC particles. After being protected by CNC-CNF coating, the NMC 811 electrodes displayed dramatically improved capacity at various charge rates as compared to conventional aqueous-based electrodes. The fabricated aqueous-processed CNC-CNF electrodes exhibit comparable capacity and much superior cycling stability compared to commercialized NMC 811 electrodes fabricated using toxic N-Methylpyrrolidone (NMP) solvent and polyvinylidene fluoride (PVDF) binder. Consequently, the developed aqueous electrode slurry is suitable for economical and environmentally friendly operational roll-to-roll manufacturing. Moreover, the developed electrode ink is appropriate for screen printing and exhibits an appropriate manufacturing capability.

As described in embodiments herein, an in situ nanocellulose protection layer for NMC 811 particles was developed through electrostatic interactions during the slurry preparation. Nanochannels were determined between inter-chains of nanocellulose through wide-angle X-ray scattering and demonstrated their ability to confine interlayer water effectively using atomistic simulations. Moreover, this nanocellulose coverage simultaneously minimizes Li+ surface segregation and mitigates water infiltration. Owing to less material decomposition during the aqueous processing, compared to unprotected electrodes, the nanocellulose-protected NMC electrodes exhibit higher capacity and initial coulombic efficiency. Compared to unprotected electrodes, the nanocellulose-protected NMC electrodes exhibit higher capacity (133 vs. 59 mAh/g at 6 C) and initial coulombic efficiency (83% vs. 62% at 0.1 C).

Additionally, the optimized water-processed NMC electrodes render superior rate capability and dramatically improved cycling stability as compared to the electrodes fabricated using the conventional toxic organic solvent, such as N-methyl-2-pyrrolidone. Consequently, the developed approach enables affordable, sustainable aqueous processing for nickel-rich NMC cathodes with superior capacity, energy density, and lifetime.

### Definitions

It is to be understood that the terminology used herein is for describing particular embodiments only and is not intended to be limiting. Unless defined otherwise, all technical and scientific terms used herein have the same meaning as commonly understood by one of ordinary skill in the art to which the disclosure pertains.

Although any methods and materials similar or equivalent to those described herein may be used in the practice for testing of the present disclosure, exemplary materials and methods are described herein.

When a list is presented, unless stated otherwise, it is to be understood that each individual element of that list, and every combination of that list, is a separate embodiment. For example, a list of embodiments presented as “A, B, or C” is to be interpreted as including the embodiments, “A,” “B,” “C,” “A or B,” “A or C,” “B or C,” or “A, B, or C.”

As used in this specification and the appended claims, the singular forms “a,” “an,” and “the” include plural referents unless the content clearly dictates otherwise. The conjunctive term “and/or” between multiple recited elements is understood as encompassing both individual and combined options. For instance, where two elements are conjoined by “and/or,” a first option refers to the applicability of the first element without the second. A second option refers to the applicability of the second element without the first. A third option refers to the applicability of the first and second elements together. Any one of these options is understood to fall within the meaning, and therefore satisfy the requirement of the term “and/or” as used herein. Concurrent applicability of more than one of the options is also understood to fall within the meaning, and therefore satisfy the requirement of the term “and/or.”

Unless the context requires otherwise, throughout the specification and claims that follow, the word “comprise” and synonyms and variants thereof such as “have” and “include”, as well as variations thereof, such as “comprises” and “comprising”, are to be construed in an open, inclusive sense, e.g., “including, but not limited to.” The transitional terms “comprising,” “consisting essentially of,” and “consisting of” are intended to connote their generally accepted meanings in the patent vernacular; that is, (i) “comprising,” which is synonymous with “including,” “containing,” or “characterized by,” is inclusive or open-ended and does not exclude additional, unrecited elements or method steps; (ii) “consisting of” excludes any element or step not specified in the claim; and (iii) “consisting essentially of” limits the scope of a claim to the specified materials or steps “and those that do not materially affect the basic and novel characteristic(s)” of the claimed invention. Embodiments described in terms of the phrase “comprising” (or its equivalents) also provide as embodiments those independently described in terms of “consisting of” and “consisting essentially of.”

“About” means within an acceptable error range for the particular value as determined by one of ordinary skill in the art, which will depend in part on how the value is measured or determined, i.e., the limitations of the measurement system. Unless explicitly stated otherwise within the disclosure, claims, result or embodiment, “about” means within one standard deviation per the practice in the art, or can mean a range of ±20%, ±10%, ±5%, ±4, ±3, ±2 or ±1% of a given value. It is to be understood that the term “about” can precede any particular value specified herein, except for particular values used in the Examples.

As used herein, “slurry” is a mixture of denser solids suspended in a liquid. In some embodiments, the liquid is the solvent. A “homogenous slurry” as described herein refers to a evenly dispersed mixture of denser solids suspended in a liquid (e.g., solvent). In a non-limiting example, the homogenous slurry is a combination of a hybrid binder, active materials, conductive materials, and a solvent. In some embodiments the slurry comprises electrode ink.

Coulombic efficiency, also referred to as Faraday efficiency, describes the efficiency with which charge (electrons) are transferred in a system facilitating an electrochemical reaction, such as, but not limited to, a battery. In electrochemical reaction systems, a source of loss in efficiency is due to unwanted side reactions, such as, but not limited to, oxidation of impurities and the formation of a solid electrolyte interface (SEI).

As used herein, “fast-charging” is the ability to efficiently and rapidly charge and discharge electrical energy. It is evaluated by the amounts of capacity at high charge/discharge currents which are described as electrodes charged/discharge at current rates equal to and above 4 C-6 C.

As used herein, “twisted molecular chains” refers to long polymer chains of a binder in screen-printable electrode ink that are physically entangled with other long polymer chains of a binder throughout the composition of the ink. The entangled molecular chains affect the properties of the inks including the viscosity and screen printability, and can potentially aggregate components of the inks. “Untwisted molecular chains” refers to long polymer chains of a binder in the screen-printable electrode ink that are not physically entangled. The decreased entanglement allows untwisted molecular chains to create many small ink units that are able to transfer through the gap in the screen to the substrate.

A “micromorphological feature” refers to inks on a micro scale such that it is referring to the characteristics of the ink's particles in relation to one another. These features impact the overall characteristics of the inks including, but not limited to, the viscosity, electrochemical properties, rheological properties, the molecular structure of the inks, how the particles interact with each other in the inks, the screen-printability of the inks, and the dispersion of each component.

Herein, “electrode ink” refers to as liquid ink that is printed on different substrates that can include but is not limited to plastic, glass, ceramic, paper, metal, wood, polymer, or composite that allows for in-situ analysis with high reproducibility, sensitivity, and accuracy. Composition of the different inks may include, but is not limited to, carbon, silver, gold, platinum, nickel, cobalt, iron, manganese, and/or lithium. “Electrode ink” is commonly used for screen-printed electrodes, but may be used for other types of electrodes that use “electrode ink.” Further, the composition of “electrode ink” may be modified through adding different materials that may include, but are not limited to, different metals, enzymes, complexing agents, polymers, and/or cellulose.

Herein, “protective layer” refers to as a layer of material that prevents solvent from interacting with a layer of material that is covered by the protective layer. The protective layer, in a non-limiting example, may trap the solvent to prevent the solvent from interacting with the layer of material that is protected. There are varying levels of protection for a “protective layer” as described herein. The protection should be at least about 50% protection up to about complete protection (about 100%) of preventing solvent from interacting with the layer of material.

Herein, “active material” or “active materials” refers to components in a cathode or anode that participate in oxidation and reduction reactions. Active materials in anodes include, but are not limited to graphite (natural graphite, synthetic graphite), silicon, silicon oxide, silicon-carbon composites, Li₄TiO₁₂, TiNb₂O₇, tin oxide, tin alloys, transition metal oxides (such as Co₃O₄, Fe₃O₄), hard carbon, and lithium titanium oxides. Active materials in cathodes include, but are not limited to lithium-metal oxides, vanadium oxides, LiFePO₄, LiMnPO₄, LiCoPO₄, LiNiPO₄, LiCOO₂, LiNiₓMn_{y}Co_{z}O₂, LiNiₓCo_{y}Al_{z}O₂ (x+y+z=1), LiMn₂O₄, LiNi_{0.5}Mn_{1.5}O₄, sulfur, FeS₂, V₂O₅.

Herein, a “current collector” is a component of a battery that facilitates flow of electrons during charging and discharging processes, allowing efficient transfer of electrons from active materials to an external circuit. The current collector supports electrode materials and is an electrical conductor between electrodes and external circuits. Some non-limiting examples of current collectors include metallic foils, mesh collectors that have a mesh-like structure, foam collectors, solid metal foils (e.g., copper, aluminum, nickel, and stainless steel), or carbon-based collectors (e.g., graphite, carbon nanotubes, and carbon-coated paper).

Herein, a “hybrid binder” refers to a combination of cellulose nanofibers (CNF) and cellulose nanocrystals (CNC). In some embodiments, the hybrid binder comprises a mass ratio of CNC to CNF of a range of about 100:0 to about 0:100. In other embodiments, the hybrid binder comprises a mass ratio of CNC to CNF of a range of about 75:25 to about 25:75. In other embodiments, the hybrid binder comprises a mass ratio of CNC to CNF of about 1:1.

### EXAMPLES

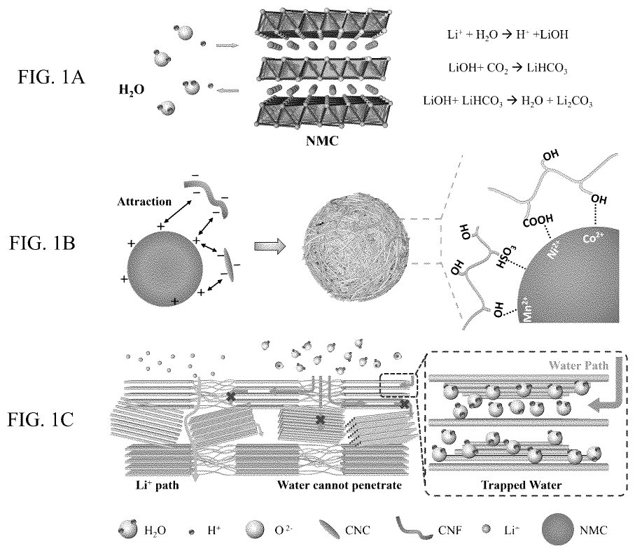

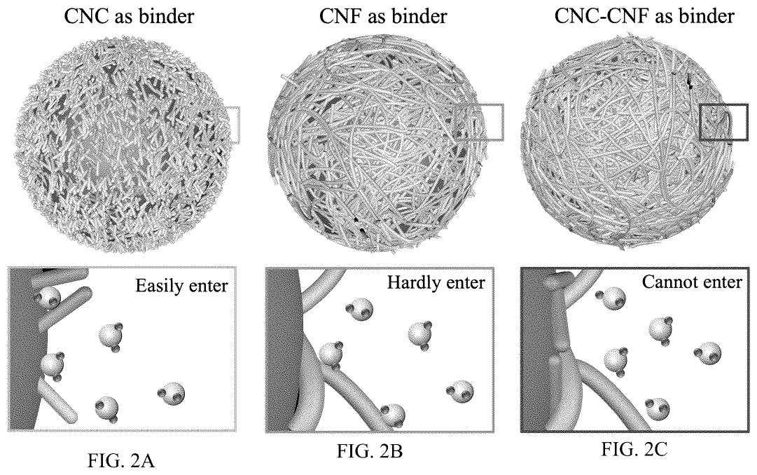

Example 1. Protection layer design for aqueous-based NMC particles. Under aqueous conditions, the decomposition of NMC materials is caused by the outward migration of Li⁺ and the inward migration of hydrogen ions (H⁺). As described in FIG. 1A, H⁺/Li⁺ ion exchange triggers a series of chemical reactions, consumes lithium resources, and forms LiOH and Li₂CO₃ deposits. It is noteworthy that the formation of LiOH diminishes the capacity of NMC electrodes, raises the pH of the slurry, and erodes the Al current collector. In some embodiments, introducing cellulose nanomaterials creates a protective layer to address and suppress these reactions. FIG. 1B illustrates the mechanism of coverage formation. As a result of possessing opposite surface charges in water, cellulose nanomaterials can be attracted by NMC particles from the negative surface charge in water of the nanocelluloses and the positive charge of the NMC particles. Surface-accessible hydroxyl (—OH) and carboxyl (—COOH) groups of cellulose nanomaterials can interact with metal ions of NMC particles. Although having the same weight content as binders, the protective effects of pure CNC, pure CNF, and hybrid CNC-CNF materials vary. The schematic FIGS. 2A-2C visualize the relationship between the morphology of cellulose nanomaterials and the corresponding protective layer. In brief, the cooperation of CNC and CNF facilitates the synthesis of a uniform, dense, and tough protection layer on the NMC particles' surface, thereby conferring a suitable water barrier property and delaying, and, in some embodiments, preventing, the continuous reaction between NMC particles and water in the aqueous atmosphere. The barrier property of cellulose nanomaterials coverage for water molecules was realized by obstructing the direct diffusion channels and increasing the tortuosity of penetration path. The accessibility of water molecules and Li⁺ in the hybrid CNC-CNF layer is intuitively portrayed in FIG. 1C. It is worth noting that although the highly tortuous structure increases the difficulty of molecular water entrance during electrode fabrication, the transfer of small lithium ions in the liquid electrolyte remains unaffected during charging and discharging.

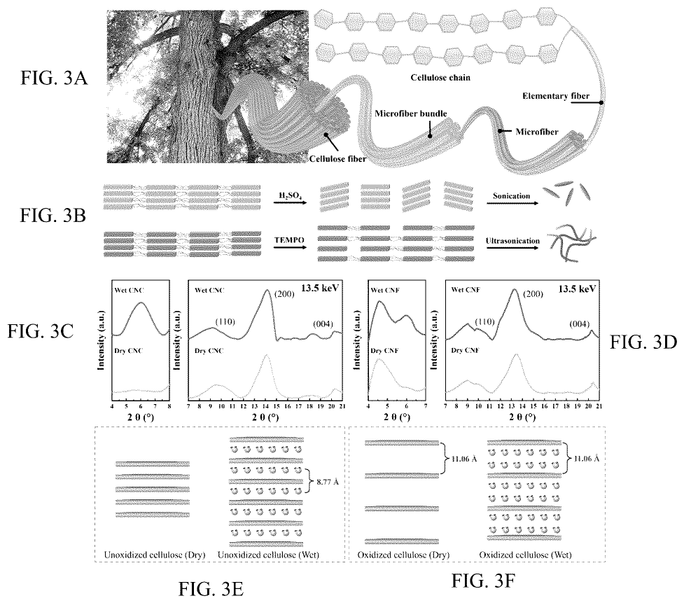

Example 2. Cellulose nanomaterials characterization. CNC and CNF are nanomaterials derived from bulk cellulose extracted in large quantities from abundant tree resources (FIG. 3A). Cellulose and water are the major components of trees, and their interactions are crucial for both fundamental research and practical applications of nanocelluloses. A deep investigation of the cellulose-water interactions is helpful to reveal the underlying mechanism that cellulose is helpful to prevent water molecule entry and proton exchange for uses described herein. Although cellulose-water interactions are essential, the related accurate structural characterization in angstrom level is highly challenging. Considering that the interfacial spacing between two cellulose chains is sub nanometer scale, the X-ray diffraction approach is one of the few feasible methods to assess the dimension of nanochannels and cellulose-water interactions. The structure of the nanochannels of CNC and CNF varies considering their different chemical groups and dimensions due to their different fabrication processes (FIG. 3B). CNC was synthesized via sulfuric acid hydrolysis, during which the disordered amorphous components were removed, and certain —OH groups were sulfonated with —HSO₃ groups. This technique hardly alters the dimensions of the nanochannels. CNF was prepared by 2,2,6,6-tetramethylpiperidine-1-oxyl (TEMPO) oxidation, leading to the replacement of a portion of —OH at C6 on glucose with a carboxyl group (—COOH). During TEMPO oxidation, substantial amounts of carboxylate and aldehyde groups are introduced, leading to an increase in electrostatic repulsion between these charged celluloses, which in turn enlarges the nanofibers inter-chain spacing. The oxidation of CNF is determined by various experimental parameters, and the celluloses are incompletely oxidized, leaving some cellulose with the original spacing. In addition, the majority of the amorphous regions of cellulose persist to create long and flexible fibers. WAXS is a powerful tool to study the crystal structure of polymers at the atomic level. Thus, WAXS at an X-ray energy of 13.5 keV with a wavelength of 0.91837 Å was employed to characterize the structure of CNC and CNF under wet and dry circumstances. The distance between two cellulose chains is calculated according to Bragg's law (Equation 1).

$$n λ = 2 d sin θ \qquad ( Equation 1 )$$

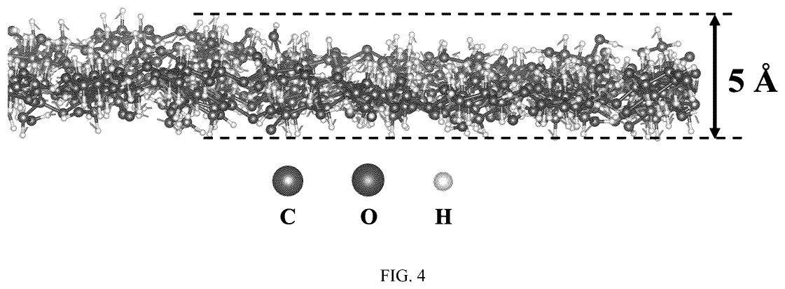

In Equation 1, λ is the X-ray wavelength, θ is the angle of incidence, d represents the distance between the atomic layers in the lattice. n is the integer number for the order of the diffraction. As shown in FIGS. 3C and 3D, both CNC and CNF exhibit representative peaks of (110), (200), and (004) at 20 values of approximately 9.50°, 13.80°, and 10.40°. In comparison to dry nanocelluloses, an additional peak was detected at 6.010 for wet nanocelluloses, indicating an interatomic spacing of 8.77 Å, and corresponding to a monolayer of water molecules that is absorbed on both sides of a cellulose chain (FIG. 3E). The monolayer of interlayer water has a thickness of 2.80 Å, while the calculated cellulose chain has a thickness of ˜5.00 Å, which coincides with the value obtained from simulation (FIG. 4). Compared to CNC, a notable peak at 4.76° is found in both wet and dry CNF samples, demonstrating an interatomic spacing of 11.06 Å. This spacing corresponds to the partially oxidized and swelled nanochannels of the inter-chain within CNF. As depicted in FIG. 3F, the structure of these swelled nanochannels is very stable and is not influenced by water molecule insertion. The spacing between two cellulose chains is 11.06 Å, indicating the fact that nanochannels of CNF can hold up to around two layers of water molecules. Simulations reveal that these interatomic spacings efficiently trap and confine water molecules, preventing their penetration into NMC particles.

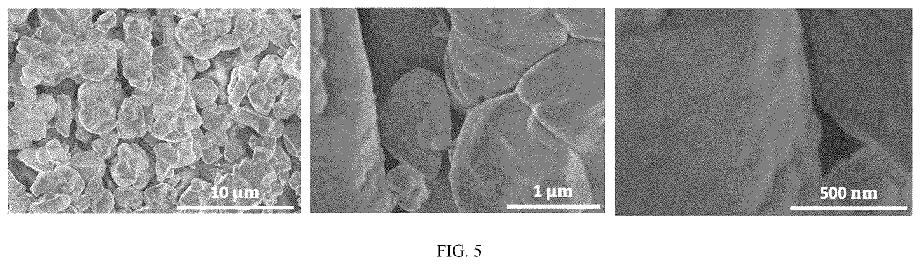

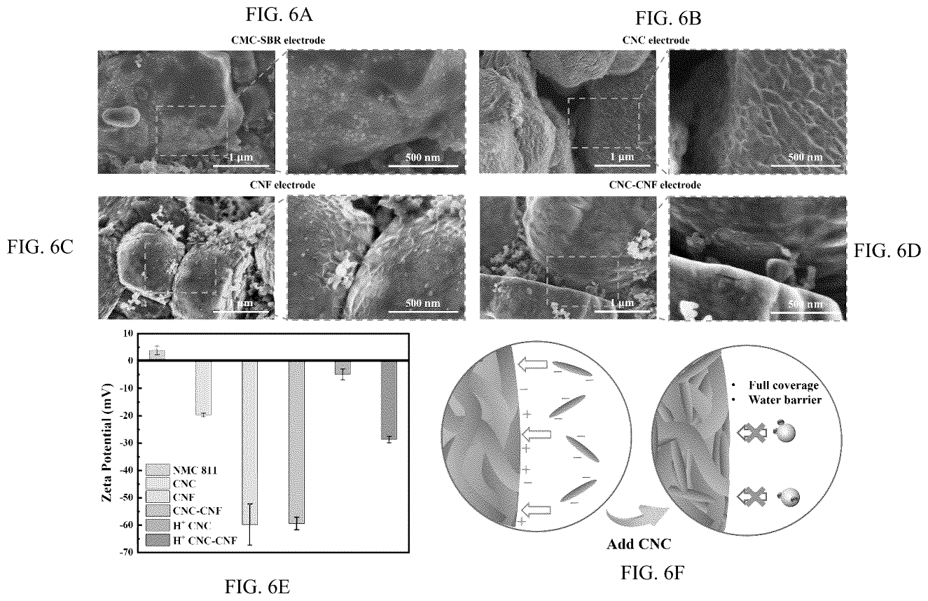

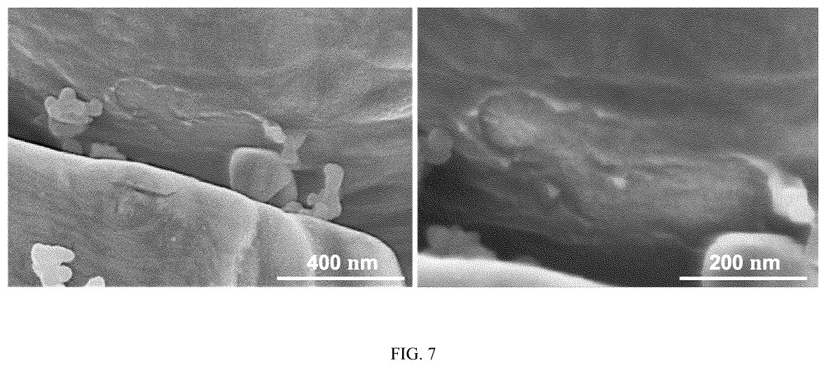

Scanning electron microscopy (SEM) was applied to visually elucidate the morphology of nanocellulose protection layers and related NMC particles. Compared to the smooth surface of pristine single crystalline NMC 811 particles (FIG. 5), the conventional aqueous electrode with carboxymethylcellulose and styrene-butadiene rubber (CMC-SBR) binder exhibited numerous inhomogeneous white dots on the NMC particles (FIG. 6A). These are likely LiOH and Li₂CO₃ deposits formed by unimpeded reactions between water molecules and NMC particles. In contrast, the CNC (FIG. 6B) and CNF (FIG. 6C) electrodes displayed fluffy, wrinkled coatings tightly wrapping the NMC particles. Comparatively, the CNC-CNF hybrid binder imparted complete NMC particle coverage. This dense and smooth coating makes it difficult to distinguish from the NMC itself. FIG. 6D shows a minor defect in the CNC-CNF coating, highlighted and colored in FIG. 7. In summary, proper functional CNC-CNF nanocellulose coatings are successfully constructed on the NMC surfaces. Among them, the ideal coating is beneficial to reducing the accession of water molecules and minimizes the NMC particle decomposition. The soluble base content test was applied to evaluate the amounts of LiOH and Li₂CO₃ side products for the aqueous-processed NMC electrodes. Through calculation, the CNC-CNF binder delivers about one-fourth of the deposit concentration of CNC-CNF electrodes than CMC-SBR electrodes (Table 1), demonstrating the outstanding protection ability of the CNC-CNF binder for NMC 811 particles in the aqueous condition.

TABLE 1
Calculated deposit concentration of water-based electrodes.

| | CMC-SBR | CNC-CNF | H⁺ CNC-CNF |
|---|---|---|---|
| Li₂CO₃ (wt. %) | 4.82 | 1.74 | 1.21 |
| LiOH (wt. %) | — | — | — |

* The concentration of LiOH is calculated to be close to 0 wt. %, which may be due to the exposure to the CO₂ atmosphere during electrode slurries fabrication and drying, which causes all the LiOH produced to be converted to Li₂CO₃.

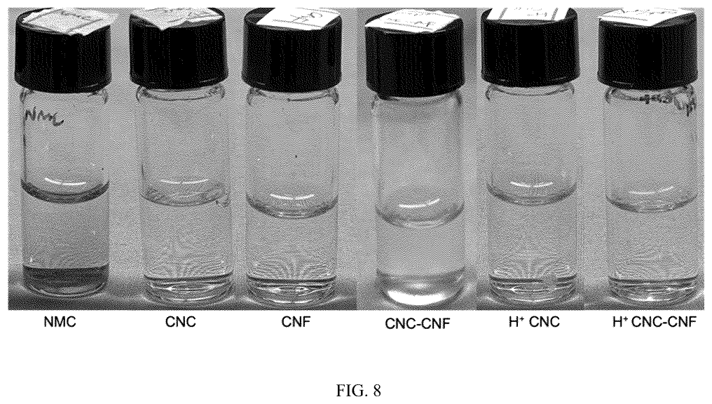

To investigate the formation of the dense CNC-CNF protective layer and understand the interaction between NMC particles and nanocelluloses in water, the surface charge of the materials was assessed. FIG. 6E presents the zeta potentials of uniform binder suspensions (FIG. 8). NMC 811 surfaces presented a positive zeta potential value of ±3.8 mV. In contrast, the nanocelluloses displayed negative values. Zeta potentials of CNC, CNF, and CNC-CNF are −20, −60, and −59 mV at the ambient temperature, respectively. More negative values indicate higher surface negative charge concentrations. Additionally, fresh hydrolyzed CNC contains some acid before dialysis, leading to less negative zeta potential values of H⁺ CNC (−5 mV) and H⁺ CNC-CNF (−29 mV). Owing to electrostatic attraction, nanocelluloses automatically migrate to positively charged NMC 811 in water, forming a dense and thin protective coating.

Moreover, the movement kinetics of these celluloses depend on their surface charge. FIG. 6F shows the formation mechanism of the CNC-CNF hybrid layer. When NMC 811 is introduced, electrostatic interaction derives CNF and CNC move toward NMC particles. Remarkably, soft CNF with a high aspect ratio and high negative charge concentrations enables it to envelop the NMC surface as a loose cobweb. Subsequently, rod-shaped CNC completes this coating layer by adhering as patches to areas on the NMC surface not fully covered by CNF since the opposite charges between CNC and NMC particles. This collaborative action results in a more complete encapsulation of the entire NMC particle than CNF or CNC alone (FIGS. 2A-2C), thus, effectively isolating the NMC particle from water.

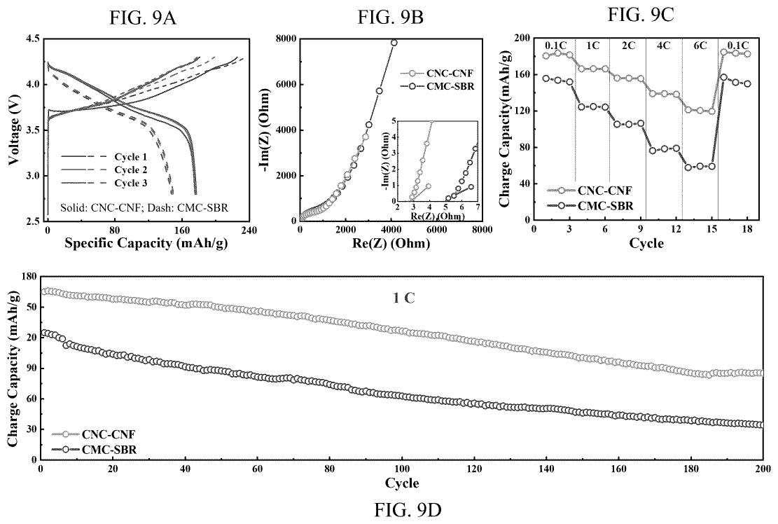

Example 3. Simulation: Electrochemical performance of electrodes. To assess the beneficial effects of nanocellulose coatings on aqueous-processed NMC electrodes, the electrochemical performance of CNC-CNF and CMC-SBR electrodes was evaluated. FIG. 9A shows the initial three galvanostatic charge-discharge curves of CNC-CNF and CMC-SBR electrodes at 0.1 C (1 C=200 mAh/g). The absence of abnormal plateaus indicates no side reactions and good electrochemical stability of these aqueous-based binders during cycling. The initial charge and discharge capacities of the CNC-CNF electrode were 225 and 175 mAh/g, respectively, with an initial coulombic efficiency of 78%. In contrast, the charge and discharge capacities of the CMC-SBR electrode were 236 and 147 mAh/g, delivering a pretty low initial coulombic efficiency of 62%. The efficiency was influenced by the creation and stability of the cathode electrolyte interface (CEI), demonstrating the complete CNC-CNF coverage reduced adverse side products, providing a much more stable CEI during charging and discharging. The following two cycles of CNC-CNF electrodes show similar capacities, indicating the commendable stability of aqueous-processed CNC-CNF electrodes. Unlike that, more energy is needed to construct the stable CEI for the CMC-SBR electrode. Concurrently, the CNC-CNF electrode rendered a much higher discharge capacity than the CMC-SBR electrode, further demonstrating that the protective effects of the CNC-CNF coating and the reduced proton exchange of NMC 811 particles in water.

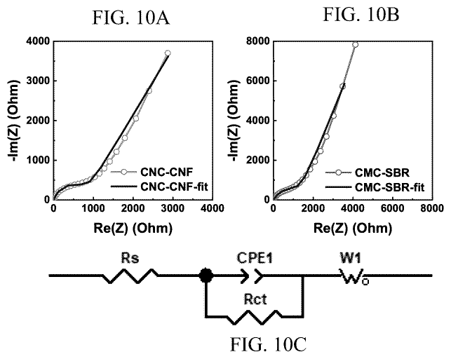

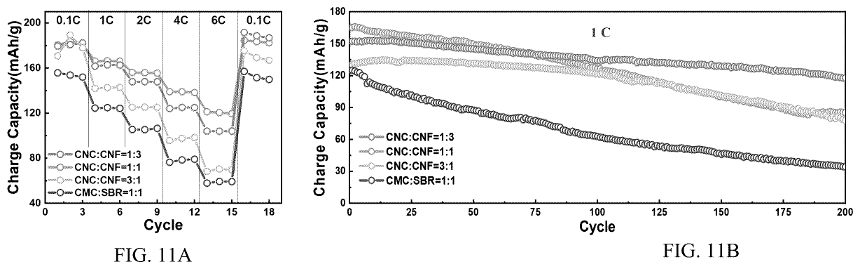

Electrochemical impedance spectroscopy (EIS) was then employed to study the resistance of aqueous-processed electrodes using different binders (FIG. 9B). The detailed analysis is listed in Table 2. Compared to its counterpart, the CNC-CNF electrode performs a lower bulk resistance, lower charge transfer resistance, and higher diffusion coefficient, suggesting the advantage of CNC-CNF coverage over the deposited side products from the proton exchange process. This low resistance is due to the barely damaged NMC 811 particles, a low amount of side products, uniform dispersion of each component, and the addition of ion-conductive nanocelluloses binder. Therefore, as-fabricated electrodes have the potential to be used for fast-charging. Further data of Nyquist plots for CNC-CNF (FIG. 10A) and CNC-SBR (FIG. 10B) are depicted in FIGS. 10A and 10B, with a schematic of the EIS circuit shown in FIG. 10C. FIG. 9C displays the rate performance of these two electrodes charged at 0.1 to 6 C. The low electronic and ionic resistances render the CNC-CNF electrode with an acceptable charge capacity of 182, 166, 156, 139, and 120 mAh/g at current densities of 0.1, 1, 2, 4, and 6 C. As the comparison sample, the CMC-SBR electrode imparts much lower average charge capacities of 154, 124, 105, 78, and 59 mAh/g at the related charge current rate. It is worth noting that the CNC-CNF electrode demonstrates a twofold increase in charge capacity than the CMC-SBR electrode at 6 C. In addition, as shown in FIG. 9D, the CNC-CNF electrode maintains a higher charge capacity than the CMC-SBR electrode throughout the 200 cycles. At the 200th cycle, the CNC-CNF electrode demonstrates nearly twice the capacity retention than the electrode using the traditional aqueous-based binder. Due to the different coating effects of CNC and CNF with various ratios on NMC particles, the final electrochemical properties are different (FIGS. 11A-11B).

TABLE 2
Bulk resistance (Rs) and charge transfer resistance
(Rct), Warburg coefficient (σ), and diffusion
coefficient (D) of aqueous-based NMC 811 electrodes.

| | CMC-SBR | CNC-CNF |
|---|---|---|
| Rs (Ω) | 3.967 | 2.578 |
| Rct (Ω) | 298.8 | 765.4 |
| σ (2 cm² s^{-0.5}) | 2074 | 1830 |
| D (cm² s⁻¹) | 3.0196 × 10⁻¹⁷ | 3.8786 × 10⁻¹⁷ |

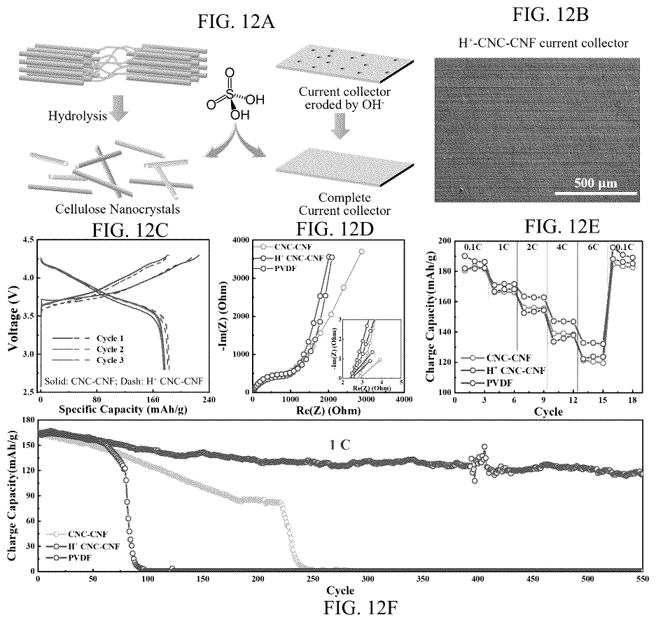

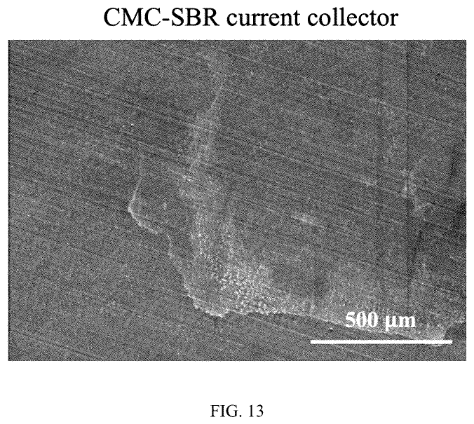

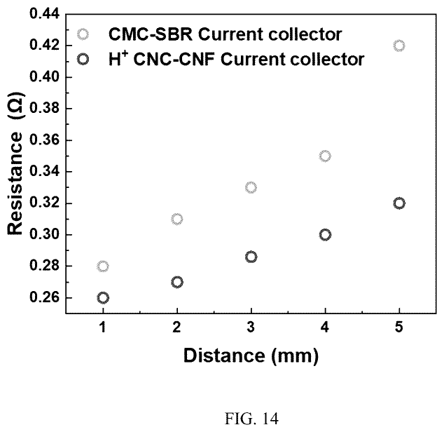

Generally, CNC is hydrolyzed using high concentrations of sulfuric acid, which are subsequently eliminated via dialysis to yield the final product. Retaining the residual acid benefits the electrochemical properties of aqueous NMC electrodes. As shown in FIG. 12A, the acid lowers the pH value of the electrode slurry, reducing Al current collector corrosion. SEM of current collectors with the electrode materials removed (FIG. 12B and FIG. 13) reveals some corrosion traces for CMC-SBR but none for H⁺ CNC-CNF. Preventing corrosion avoids decreasing the electronic conductivity of the current collector (FIG. 14) and ensures electrode-collector contact.

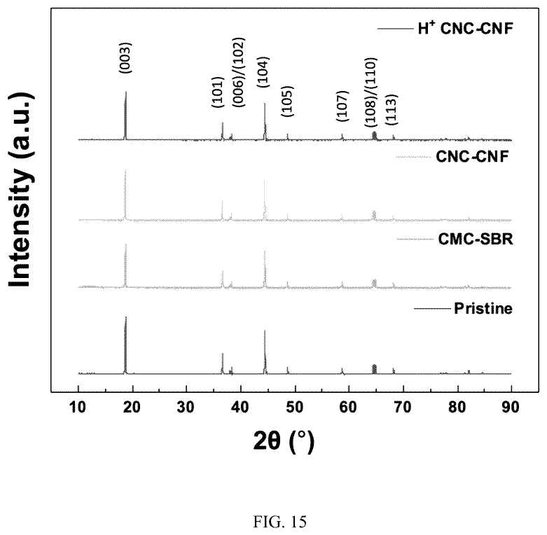

To evaluate the effects of H⁺ CNC-CNF, CNC-CNF, and CMC-SBR binders for NMC particle protection, X-ray diffraction (XRD) analysis of NMC 811 before and after mixing with these binders is presented in FIG. 15. For the XRD analysis, all samples exhibited clear split of (108) and (110) peaks around 2θ=65°, indicating that the bulk structure and layered structure of NMC particles are well maintained since the reaction occurred on the surface. However, the integrated intensity ratio of (104) and (003), I(104)/I(003), are various. Specifically, The I(104)/I(003) values of pristine NMC 811 particles (0.668) were nearby that of CNC-CNF (0.686) and H⁺ CNC-CNF (0.660) composited particles while essentially different from that of the NMC particles covered by CMC-SBR (0.834). Therefore, compared to other coverages, the CMC-SBR layer exhibited poorer protectability.

Through comparison, NMC particles mixed with the CMC-SBR binder exhibit the worst structural damage, while the H⁺ CNC-CNF performs the best protectability for NMC particles. Meanwhile, skipping the dialysis step reduces both the duration and expenses, rendering it appropriate for the industrialization of aqueous-processed NMC electrodes. Further investigations about CNC-CNF aqueous electrodes with and without acid were characterized. FIG. 12C compares the initial three charge-discharge cycles of CNC-CNF and H⁺ CNC-CNF electrodes. No additional plateaus were observed, indicating that the acid did not cause any unexpected reaction. Moreover, the acid-included electrode provides a higher initial discharge capacity (181 vs. 175 mAh/g) and superior initial coulombic efficiency (83% vs. 78%) than the CNC-CNF electrodes because of the formation of a more stable CEI. Both electrodes show similar capacities in the subsequent two cycles, suggesting reasonable stability.

Based on an assessment of the economic, environmental, and operational advantages, it is desirable that aqueous-processed NMC electrodes can render electrochemical performances that are equal to, or possibly superior to, those of commercial NMC electrodes manufactured using NMP solvent. If excellent electrochemical properties can be achieved, it is possible to facilitate the widespread adoption and commercialization of aqueous-processed NMC electrodes in industries. Consequently, the electrochemical performances of the aqueous-based NMC electrode utilizing an optimized nanocellulose binder were evaluated in comparison to the NMP-based NMC electrode employing the PVDF binder. FIG. 12D depicts Nyquist plots of CNC-CNF, H⁺ CNC-CNF, and PVDF electrodes. A marginal reduction in bulk resistance is observed in the acid-containing electrodes, which can be attributed to the fact that acid buffers electrode slurry, consequently ensuring excellent contact between the electrode and the current collector. Moreover, the bulk resistance of the PVDF electrode is similar to that of the H⁺ CNC-CNF electrode.

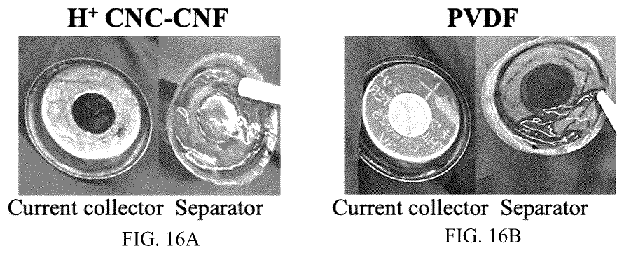

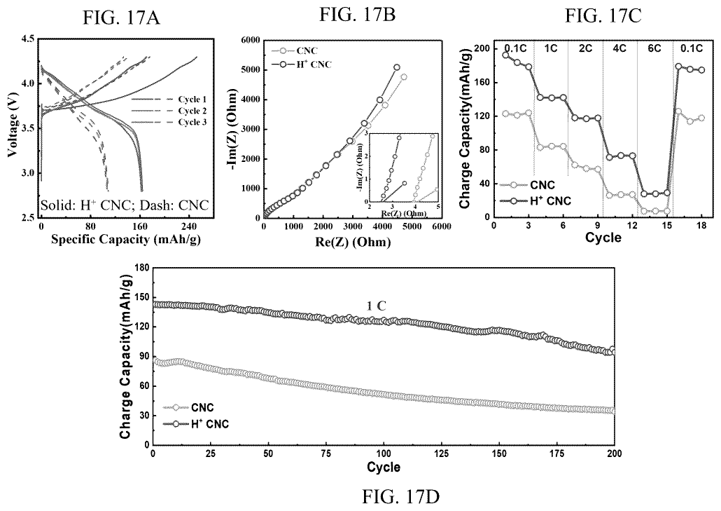

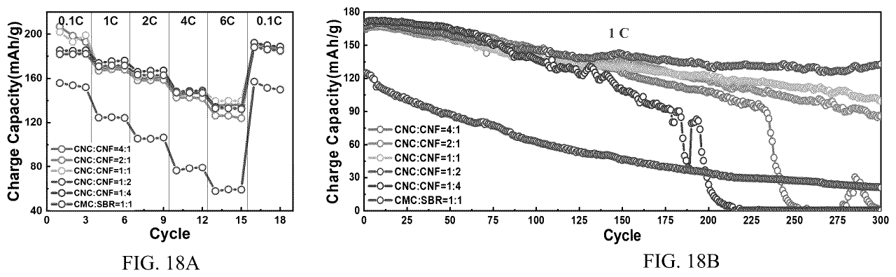

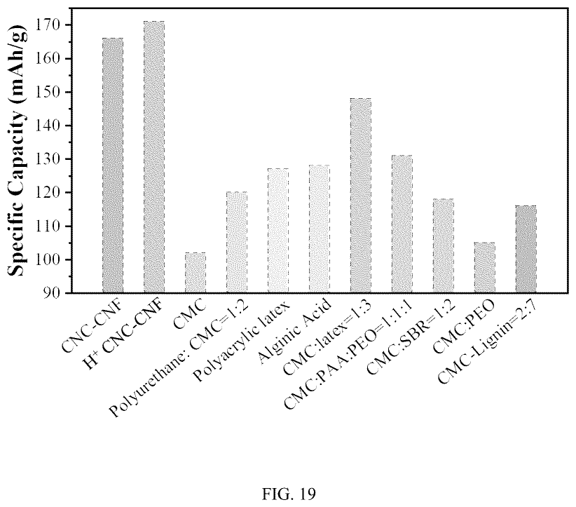

FIG. 12E presents the charge capacities of the above-mentioned electrodes at various rates. At a low current rate of 0.1 C, the capacity of all electrodes is around 182 mAh/g without a distinguishable difference. At all current rates, the PVDF electrode exhibits a similar charge capacity to the CNC-CNF electrode, while both perform slightly lower than the H⁺ CNC-CNF electrode. For example, at 6 C, the H⁺ CNC-CNF, CNC-CNF, and PVDF electrodes exhibit charge capacities of 133, 120, and 123 mAh/g, respectively. In addition to maintaining improved rate performance comparable to PVDF electrodes, the aqueous-based electrodes, especially the H⁺ CNC-CNF electrode, display enhanced cycle stability due to their superior bonding capability between electrode and current collectors. As displayed in FIG. 12F, the H⁺ CNC-CNF electrode has a capacity of 137 mAh/g with capacity retention of 80% at the 300 cycles and a capacity of 118 mAh/g at the 550 cycles under the current rate of 1 C, which is much stabler than the CNC-CNF and PVDF electrodes. All cells were evaluated using around 200 μm thin Li metal as anode. During the cycling, the CNC-CNF electrode exhibits a slow decrease in capacity while at the 223^{rd} cycle, the charge capacity of the CNC-CNF electrode suddenly drops. In contrast, the PVDF electrode shows a more pronounced capacity degradation. This electrode presents signs of decay after 60 cycles and witnessed excessive deterioration starting from the 80^{th} cycle. The improved electrochemical stability is likely due to the establishment of a stable connection between the electrode and the current collector. FIGS. 16A-16B display the disassembled coin cells after the cycling test. The H⁺ CNC-CNF electrode is tightly connected to the current collector. In contrast to this, the connection between the PVDF electrode and the current collector breaks, and the PVDF electrode sticks to the separator. The high adhesion strength results from the heightened hydrogen bonding between the —COOH group of CNF and the —OH groups on the surface of NMC and the current collector. For the aqueous-processed NMC electrodes, acid plays an important role, especially for pure CNC binders (FIGS. 17A-17D). The electrochemical properties of electrodes also depend on CNC:CNF ratios, as in the previous discussion, electrodes consisting of varying H⁺ CNC:CNF ratios render different electrochemical performances (FIGS. 18A-18B). Compared to published aqueous binders, nanocelluloses provide a higher capacity for aqueous NMC electrodes at about 1 C (FIG. 19).

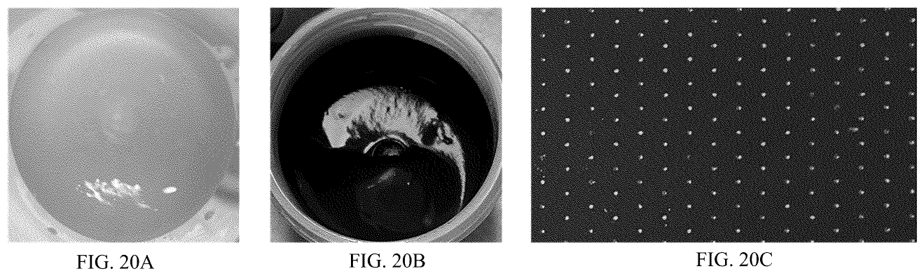

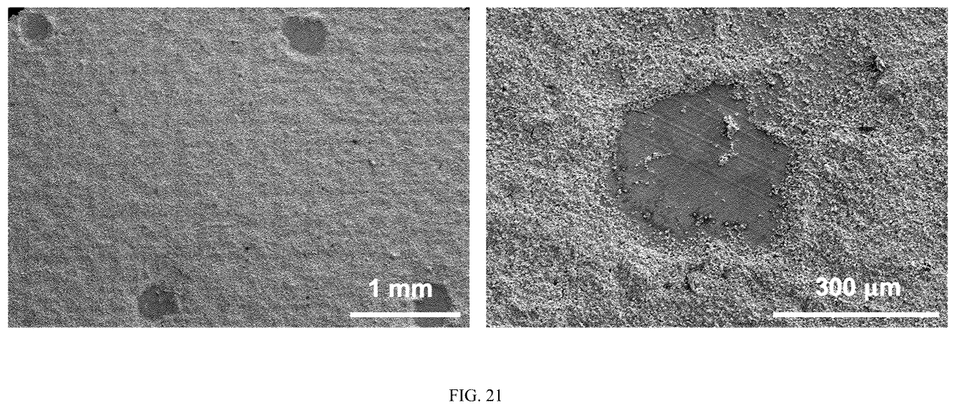

Profiting from the excellent electrochemical performances of nanocelluloses-protected NMC electrodes during water processing, their commercialization can be further realized. Furthermore, the H⁺ CNC-CNF electrode slurry has exhibited adequate engineering properties for architecture customization. Since the unique structure of CNC and CNF prevents their mixture from forming a highly twisted network for dragging the particles, the slurry is readily squeezed through the tiny gaps in the screen to render tailored patterns with the electrodes (FIGS. 20A-20C). SEM images of the screen-printed electrode elucidate the clear pores (FIG. 21), indicating that it has the potential to enable the realization of specialized functionalities by screen printing various structures.

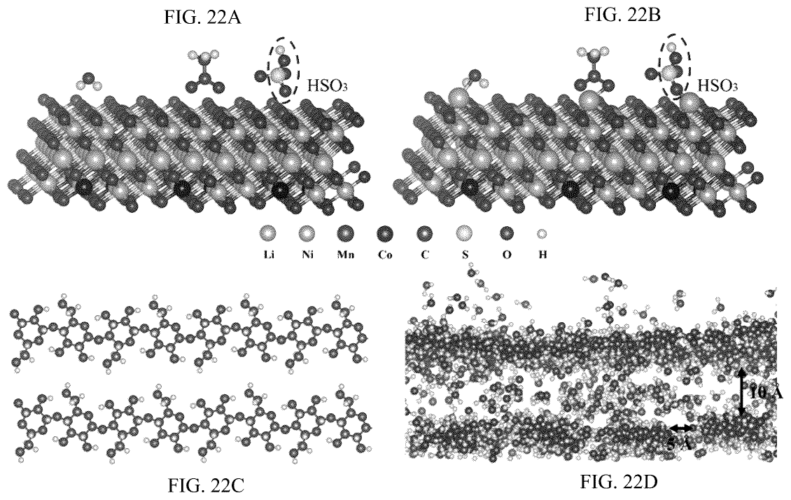

Example 4. Computational studies for CNC and CNF assessment. To understand the protective effects of CNC and CNF coating on NMC particles, the DFT calculations were performed to predict the adsorption energies of the H₂O molecule, —R—COO (the functional group of CNF, R represents C₅H₇O₄ and is simplified as CH₃ to reduce calculation cost), and —HSO₃ (the functional group of CNC) on the surface of NMC electrode and the surface segregation energy of Li in the NMC electrodes covered by these surface adsorbates. Herein, the adsorption energies were calculated by subtracting the energies of the isolated components from the energy of the adsorbed system (FIG. 22A). More negative adsorption energy indicates stronger binding of the adsorbate to the NMC surface. The computational results in Table 3 show that the adsorption energies of —R—COO and —HSO₃ groups are lower than those of H₂O, suggesting a higher tendency for the CNF and CNC functional groups to cover the NMC surface than water. This result explains why CNF and CNC can tightly wrap the NMC particles and form the coating (FIGS. 6A-6F). Moreover, the Li surface segregation energy was calculated as the energy difference between the configurations with Li in the bulk region and the surface of the NMC electrode (FIG. 22B). The negative value of Li surface segregation energy indicates a higher tendency for the adsorbate to attract Li ions to the surface. The results described herein show that the NMC electrode covered by H₂O would have negative Li surface segregation (i.e., −1.17 eV), whereas the NMC covered by —R—COO and —HSO₃ groups have positive Li surface segregation energies. This result suggests that the presence of polymer coatings containing —R—COO and —HSO₃ groups could impede the Li ions migration towards the NMC surface, thus offering protection against Li⁺ depletion and degradation. Notably, the NMC covered by —R—COO was predicted to have even higher positive Li surface segregation energy, as shown in Table 3, than that of the NMC covered by HSO₃, implying that polymer CNF with —R—COO groups would exhibit better performance in preventing Li segregation to the surface than polymer CNC. This computational prediction is consistent with the experimental observation (FIG. 9C) that CNF (with —R—COO groups) coated electrode has higher discharge capacity than CNC (with —HSO₃ groups) coated electrode. In summary, the DFT results described herein indicate that functional groups —R—COO and —HSO₃ of the polymer coating tend to cover the NMC surface and further effectively impede the loss of Li from the NMC electrode in an aqueous environment.

TABLE 3
Calculated adsorption energies and Li surface segregation
energies of various adsorbates on NMC surface.

| | H₂O | —R—COO | —HSO₃ |
|---|---|---|---|
| Adsorption Energy (eV) | 0.52 | 0.37 | 0.46 |
| Li Segregation Energy (eV) | −1.17 | 0.43 | 0.09 |

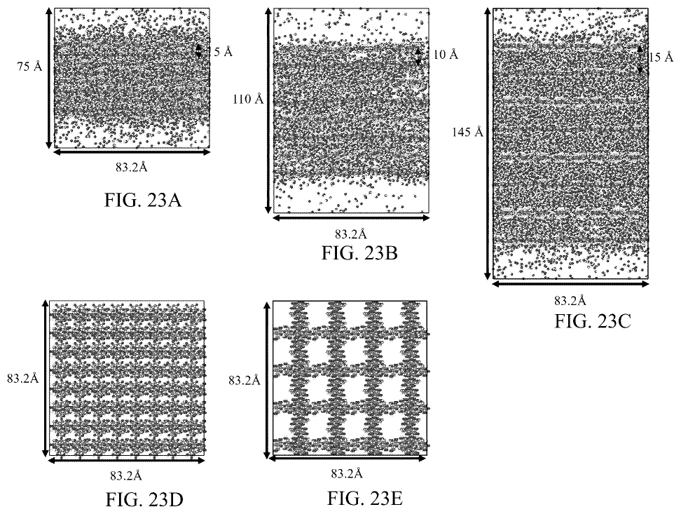

Furthermore, Molecular Dynamics (MD) simulations were carried out to gain insights into the interaction between liquid water and the main chain of CNC and CNF polymer coating. The porous structure of the main chain of CNC and CNF coating was the same and modeled by repeatedly packing the cellulose polymer chains (shown in FIG. 22C) in parallel in one layer and rotating the chains by 900 in the subsequent layer, as shown in FIGS. 23A-23E. The separation of the polymer chains was set to be 5 Å within each layer, whereas the interlayer spacing was varied to be 5 Å, 10 Å, and 15 Å, respectively. The H₂O molecules with a density close to that of liquid water (i.e., 1 g/cm³) were added into the space between the cellulose chains. FIG. 22D shows an equilibrated structure of the system after 100 ps of MD simulation. The MD simulations show that a small amount of H₂O could diffuse out of the polymer coating while most of the H₂O could be retained inside the polymer coating. Quantitatively, the MD simulations predicted that the cellulose coating with an interlayer spacing of 10 Å keeps the highest ratio of water inside (94%) as compared to 91% with 15 Å interlayer spacing and 72% with 5 Å interlayer spacing. The same trend has also been observed from the MD simulations for the cellulose coating with a chain separation of 15 Å within each layer. It should be mentioned that the analysis of WAXS patterns shows the spacing in CNF is larger than that in CNC. Consequently, the MD simulation results suggest that an increase in the interlayer spacing in the TEMPO-oxidized CNF could be beneficial in retaining water within the coating and protecting NMC from water-induced damage during aqueous processing. Thus, the MD simulation results explain the observed improvement in initial discharge capacity and initial Coulombic efficiency of the CNF-coated electrode compared to the CNC-coated electrode.

Conclusion. This work effectively and facilely fabricated aqueous-based NMC 811 electrodes with comparable charge capacity and superior cycling stability than electrodes fabricated using NMP solvent. Earth-abundant, sustainable, biodegradable, highly designable, and inexpensive cellulose nanomaterials binders were applied as protectors to create a protective layer for NMC particles to obstruct water molecules entrance and the following NMC structural decomposition. Cellulose nanomaterials, in this case specifically CNC and CNF, have a surface charge opposite to that of NMC, enabling them to move forward expeditiously and adsorb onto NMC particles, establishing a protection coverage. CNF exhibited lower surface negative charges than CNC, granting it greater kinetic and more rapid migration to NMC particles for forming a sparse primary network. Subsequently, due to the uncovered regions offering positive surface charge, the CNC automatically moved and covered the exposed areas to complete a dense CNC-CNF coverage for NMC particles. The CNC-CNF coverage raised the tortuosity and elevated the difficulty for water molecules entrance, while the transference of Li⁺ is unaffected in the liquid electrolyte.

In comparison to NMC electrodes compositing of conventional CMC-SBR, CNC-CNF coverage provided aqueous-based NMC electrodes with superior charge capacities at current densities from 0.1 to 6 C. For instance, the CNC-CNF electrode (146 mAh/g) delivered a much higher discharge capacity than the CMC-SBR electrode (106 mAh/g) at 6 C. Interestingly, the leftover sulfuric acid from the CNC hydrolysis procedure proved to be a valuable additive for ensuring the integrity of Al current collector and enhancing the capacity of aqueous-based NMC electrodes. After optimization, the H⁺ CNC-CNF electrode performed a charge capacity of 158 mAh/g at 6 C. Compared to the widely commercialized NMP-based NMC electrodes utilizing PVDF binder, the aqueous-based NMC electrode consisting of the optimized H⁺ CNC-CNF binder exhibited comparable rate performance and superior cycling stability. The improved cycling stability afforded by the H⁺ CNC-CNF binder has the capability to sustain contact between the electrode and current collector. Furthermore, the prepared aqueous-based NMC ink can be facilely employed to manufacture structure tailorable electrodes while satisfying the inexpensive, no toxicity, effortless control, and eco-friendly demands. Therefore, it is anticipated that this aqueous-based NMC electrode can replace the existing product line using NMP as a solvent, significantly expanding the market prospect for NMC LIBs in the future.

Materials. Microcrystalline cellulose, 98% sulfuric acid, 2,2,6,6-tetramethylpiperidine-1-oxyl (TEMPO), sodium bromide (NaBr), Sodium hypochlorite solution (NaClO solution), and polyvinylidene fluoride (PVDF) were procured from Sigma-Aldrich, USA. Carboxymethyl cellulose sodium salt (CMC) was purchased from Thermo Scientific™ USA. Single crystalline NMC 811 was obtained from Easpring Material Technology Co., LTD., China. Super P, Styrene-butadiene rubber (SBR) solvent (50 wt. % in water), and Al foil current collector were procured from MTI Co., USA. NMP was procured from Fisher Science Education, USA. Before ink preparation, NMC 811 and Super P powders were dried in a vacuum oven (MTI Co., USA) for at least 12 h at 100° C.

CNC Synthesis. The CNC acid hydrolysis process was based on previous work.[32] In brief, 30 g microcrystalline cellulose was mixed with 300 mL 64 weight percent (wt. %) sulfuric acid under constant mechanical stirring for 40 minutes (min) at 45° C. Ten times the volume of water was applied to terminate the reaction. The suspensions were washed with deionized (DI) water using centrifuging (Thermo Scientific™, USA) at 4000 rpm. Once the supernatant became turbid, the centrifuge step was done. The pH of the collected supernatant was 1.33. To remove the remaining acid, the resulting suspensions were dialyzed with DI water using dialysis membranes (molecular weight cutoff of 12,000-14,000) until the pH of the water was around 7.

CNF Synthesis. CNF was prepared by TEMPO-mediated oxidation following mechanical disintegration.[33] In brief, softwood pulp (20 g with about 85% water content) was dispersed using mechanical stirring for 2 hours. And then, TEMPO (0.02 g/g) and NaBr (0.15 g/g) solutions were mixed, and 10 mmol/g of 12.5% NaClO solution was added dropwise. Following that, 0.5 mol/L NaOH solution was applied to adjust and keep the pH to 10.5 overnight. The oxidation reaction was terminated by 5 mL of ethanol. The synthesized CNF was washed and filtrated using DI water. The final suspension was well-dispersed in an ice bath with a Prob sonicator (Sonics & Materials, Inc.)

Electrodes preparation. The binders were dissolved into the corresponding solvents to achieve the concentration of 3 wt. % before use. The active materials, Super P, and binder were added with a weight ratio of 92:5:3. In the absence of special instructions, the ratio of the masses of CNC and CNF in the CNC-CNF hybrid binder is 1:1. After all components were evenly mixed, the slurry were coated on Al foil using a doctor blade. Electrodes were dried in a desiccator and transferred into a vacuum oven for at least 4 hours (h) at 100° C. before transferring to the glove box.

Characterization methods. The x-ray diffraction (X'Pert Pro, Philips) was used to characterize the structure and orientation of CNC and NMC particles that were pretreated with various binders. Before XRD measuring, the NMC and binders were mixed with a weight ratio of 92:3, which consist of that in electrodes. The morphology of the samples was observed using a Hitachi S4800 SEM set at 3 kV. Nano ZS Zetasizer (Malvern) was applied to measure the zeta potential of NMC particles and cellulose nanomaterials in water.

Electrochemistry characterization. The electrolyte used in all electrochemical tests was 1.2 M LiPF6 dissolved in EC:EMC=3:7 by weight (Gen 2). During the assembly, 80 μL of electrolyte was added to the cell assembly. The separator was Celgard 2400 (25 μm in thickness). The active materials mass loading of the electrode was about 4.5 mg/cm². EIS was done at room temperature using an electrochemical station (Biologic SP150) in the frequency range of 1 MHz to 100 mHz. A LANDT 8-channel tester (Wuhan LAND Electronic Co., Ltd.) was used for galvanostatic testing. The rate performance was discharged at C/3 and charged at various C-rates, 0.1 C for six cycles, then 1 C, 2 C, 4 C, and 6 C for three cycles, and finally recovered to 0.1 C for another three cycles. Voltage hold at 4.3 V was applied to the 2, 4, and 6 C. The total charge time was set as 30, 15, and 10 min, respectively. The cycling stability test was charged at 1 C and discharged at C/3. All cells were initially activated at 0.1 C for six cycles. All electrochemical measurements were performed at room temperature.

The soluble base content test. 100 g of de-ionized (DI) water was mixed with 1 g electrode powder in a flask for 10 minutes. Subsequently, the slurry was promptly subjected to filtration. 90 g of the filtrated solution was employed for the pH titration experiment in a 250 ml glass flask. Throughout the pH titration experiment, the pH meter was placed into the transparent solution while swirling it. The acid with a concentration of 0.01 M was introduced into the solution. The amounts of acid applied in the two inflection points, pH values of 8.4 and 4.7, were recorded. The weight percent of LiOH and Li₂CO₃ are calculated following equations 2 and 3.

$$Li 2 CO 3 ( wt . \% ) = \frac{( V 2 - V 1 ) \times {C}_{HCl} \times {M}_{Li 2 CO 3}}{1000 \times \{ ( {W}_{NMC} \times {W}_{solution} ) / {W}_{DI water} \}} \qquad ( Equation 2 )$$

$$LiOH ( wt . \% ) = \frac{( 2 \times V 1 - V 2 ) \times {C}_{HCl} \times {M}_{LiOH}}{1000 \times \{ ( {W}_{NMC} \times {W}_{solution} ) / {W}_{DI water} \}} \qquad ( Equation 3 )$$

The V1 and V2 are ml of acid used at two inflection points, in which V2>V1; C is the concentration of HCl; W and M are weights and molecular weights of related materials.

Density functional theory calculation. All the DFT calculations were performed using the Vienna Ab initio Simulation Package (VASP) with plane wave basis associated with projector augmented wave approach. Exchange correlation was treated with generalized gradient approximation (GGA) in the form of Perdew-Birke-Ernzerhof (PBE) functional. As in GGA+U calculations, the effective on-site Coulomb interaction parameters for Ni, Co, and Mn were set to be 6.4 eV, 4.9 eV, and 4.5 eV, respectively. In all the calculations, the plane-wave cutoff energy was set as 500 eV, and the total energy of the system converged within 10⁻⁵ eV. The surface of the NMC electrode was modeled using a slab structure containing 27 transition metals (21 Ni atoms, 3 Mn atoms, and 3 Co atoms). The Li surface segregation was modeled by moving one Li atom at the subsurface layer to the surface 3b site and leaving a Li vacancy in the subsurface coating. During structural relaxation, the atomic positions of the bottom four layers were fixed, and the force acting on each atom converged to below 0.02 eV/Å. The structural optimization calculations used a 4×4×1 Monkhorst-Pack k-point mesh.

Molecular dynamics simulations. The molecular dynamics simulations were performed by using a Large-scale Atomic/Molecular Massively Parallel Simulator (LAMMPS) package. The polymer consistent force field (PCFF) was used to describe both bonding and non-bonding interactions between atoms. Columbic potential was calculated using the Ewald summation method. The cutoff distance of force was set to be 10 Å. Each cellulose chain was constructed with 8 cellobiose repeating units. The functional groups of CNC and CNF are not considered in MD simulations for the efficiency of simulations. The simulation cell has an orthorhombic shape. The cellulose chains were arranged in parallel along [100] direction in a layer and along [010] direction in a subsequent layer, resulting in an interlaced pattern along [001] direction and porous structure. The dimension of the porous cellulose structure is 83.2 Å in the [100] and [010] directions and ranges from 75 Å to 145 Å in the [001] direction, as shown in FIGS. 20A-20C. To model water-cellulose interaction, H₂O molecules were added into the space between the cellulose chains. Specifically, we added 3220 H₂O molecules into the cellulose with a 5 Å interlayer spacing, 6440 H₂O molecules into the cellulose with a 10 Å interlayer spacing, and 9660 H₂O molecules into the cellulose with a 15 Å interlayer spacing, ensuring a consistent H₂O density (close to liquid water density, 1 g/cm³) within the interlayer space of cellulose supercells.

The MD simulation procedure is as follows: Geometry optimization was conducted on the water-cellulose structure until the energy tolerance of 0.0001 kcal/mol and force tolerance of 0.005 kcal/mol/A were satisfied. Subsequently, the structure was equilibrated by performing a cycle of annealing simulation. During annealing, the structure was heated from 300 to 500 K and cooled back to 300 K at intervals of 40 K. Each temperature stage was held for 0.1 ps, and the total time for a cycle of annealing was 1 ps. Finally, the equilibrated water-cellulose configurations were obtained through NVT (constant particle number, volume, and temperature) MD simulations at 600K. The positions of cellulose were fixed during the NVT simulation. Each NVT simulation had 100,000 steps, and each step took for 1 fs. The choice of a relatively high temperature of 600K was intended to accelerate the molecular dynamic processes.

Supporting Information. With the number of nanomaterials, the rod-like CNC lack the connection with each other, and it is hard to form a continual protection film. Different from the CNC, CNF is long enough to be stacked on each other and generate an excellent film to limit water molecules while maintaining some uncovered regions. Superior to using only CNF, the CNC introduction assists in filling the small gaps between the randomly stacked fibers and creating a denser coverage.

All samples exhibited clear split of (108) and (110) peaks around 2θ=65°, indicating the bulk structure and layered structure of NMC particles are well maintained since the reaction occurred on the surface. However, the integrated intensity ratio of (104) and (003), I(104)/I(003), are various. Specifically, The I(104)/I(003) values of pristine NMC 811 particles (0.668) were nearby that of CNC-CNF (0.686) and H⁺ CNC-CNF (0.660) composited particles while essentially different from that of the NMC particles covered by CMC-SBR (0.834). Therefore, compared to other coverages, the CMC-SBR layer exhibited poorer protectability.

### REFERENCES

[1] D. Andre, S.-J. Kim, P. Lamp, S. F. Lux, F. Maglia, O. Paschos, B. Stiaszny, Future generations of cathode materials: an automotive industry perspective, Journal of Materials Chemistry A 3(13) (2015) 6709-6732.
[2] S.-T. Myung, F. Maglia, K.-J. Park, C. S. Yoon, P. Lamp, S.-J. Kim, Y.-K. Sun, Nickel-rich layered cathode materials for automotive lithium-ion batteries: achievements and perspectives, ACS Energy Letters 2(1) (2017) 196-223.
[3] P. Teichert, G. G. Eshetu, H. Jahnke, E. Figgemeier, Degradation and aging routes of Ni-rich cathode based Li-ion batteries, Batteries 6(1) (2020) 8.
[4] M. Wood, J. Li, R. E. Ruther, Z. Du, E. C. Self, H. M. Meyer III, C. Daniel, I. Belharouak, D. L. Wood III, Chemical stability and long-term cell performance of low-cobalt, Ni-Rich cathodes prepared by aqueous processing for high-energy Li-Ion batteries, Energy Storage Materials 24 (2020) 188-197.
[5] L. Zou, Y. He, Z. Liu, H. Jia, J. Zhu, J. Zheng, G. Wang, X. Li, J. Xiao, J. Liu, Unlocking the passivation nature of the cathode-air interfacial reactions in lithium ion batteries, Nature communications 11(1) (2020) 3204.
[6] I. A. Shkrob, J. A. Gilbert, P. J. Phillips, R. Klie, R. T. Haasch, J. Bareno, D. P. Abraham, Chemical weathering of layered Ni-rich oxide electrode materials: evidence for cation exchange, Journal of The Electrochemical Society 164(7) (2017) A1489.
[7] L. Azhari, X. Zhou, B. Sousa, Z. Yang, G. Gao, Y. Wang, Effects of Extended Aqueous Processing on Structure, Chemistry, and Performance of Polycrystalline LiNi x Mn y Co z O2 Cathode Powders, ACS Applied Materials & Interfaces 12(52) (2020) 57963-57974.
[8] I. Hamam, N. Zhang, A. Liu, M. Johnson, J. Dahn, Study of the reactions between Ni-rich positive electrode materials and aqueous solutions and their relation to the failure of Li-ion cells, Journal of the Electrochemical Society 167(13) (2020) 130521.
[9] I. Doberdò, N. Löffler, N. Laszczynski, D. Cericola, N. Penazzi, S. Bodoardo, G.-T. Kim, S. Passerini, Enabling aqueous binders for lithium battery cathodes-Carbon coating of aluminum current collector, Journal of power sources 248 (2014) 1000-1006.
[10] C. Yuan, H. Cao, K. Shen, Y. Deng, D. Zeng, Y. Dong, M. Hauschild, Water-based manufacturing of lithium ion battery for life cycle impact mitigation, CIRP Annals 70(1) (2021) 25-28.
[11] N. Loeffler, G. T. Kim, F. Mueller, T. Diemant, J. K. Kim, R. J. Behm, S. Passerini, In situ coating of Li [Ni0. 33Mn0. 33Co0. 33] O2 particles to enable aqueous electrode processing, ChemSusChem 9(10) (2016) 1112-1117.
[12] M. Memm, A. Hoffmann, M. Wohlfahrt-Mehrens, Water-based LiNi1/3Mn1/3Co1/3O2-cathodes with good electrochemical performance by use of additives, Electrochimica Acta 260 (2018) 664-673.
[13] W. Bauer, F. A. Qetinel, M. Müller, U. Kaufmann, Effects of pH control by acid addition at the aqueous processing of cathodes for lithium ion batteries, Electrochimica Acta 317 (2019) 112-119.
[14] A. Kazzazi, D. Bresser, A. Birrozzi, J. von Zamory, M. Hekmatfar, S. Passerini, Comparative analysis of aqueous binders for high-energy li-rich NMC as a Lithium-Ion cathode and the impact of adding phosphoric acid, ACS applied materials & interfaces 10(20) (2018) 17214-17222.
[15] S. Radloff, R.-G. Scurtu, M. Holzle, M. Wohlfahrt-Mehrens, Applying Established Water-Based Binders to Aqueous Processing of LiNi0. 83Co0. 12Mn0. 0502 Positive Electrodes, Journal of The Electrochemical Society 168(10) (2021) 100506.
[16] S. Radloff, R.-G. Scurtu, M. Holzle, M. Wohlfahrt-Mehrens, Water-based LiNi0. 83Co0. 12Mn0. 0502 electrodes with excellent cycling stability fabricated using unconventional binders, Journal of The Electrochemical Society 169(4) (2022) 040514.
[17] H. Zhu, W. Luo, P. N. Ciesielski, Z. Fang, J. Zhu, G. Henriksson, M. E. Himmel, L. Hu, Wood-derived materials for green electronics, biological devices, and energy applications, Chemical reviews 116(16) (2016) 9305-9374.
[18] H. Lu, J. Hagberg, G. Lindbergh, A. Cornell, Li4Ti5O12 flexible, lightweight electrodes based on cellulose nanofibrils as binder and carbon fibers as current collectors for Li-ion batteries, Nano Energy 39 (2017) 140-150.
[19] H. Lu, M. r. Behm, S. Leijonmarck, G. r. Lindbergh, A. Cornell, Flexible paper electrodes for li-ion batteries using low amount of TEMPO-oxidized cellulose nanofibrils as binder, ACS Applied Materials & Interfaces 8(28) (2016) 18097-18106.
[20] O. El Baradai, D. Beneventi, F. Alloin, Y. Bultel, D. Chaussy, Use of cellulose nanofibers as an electrode binder for lithium ion battery screen printing on a paper separator, Nanomaterials 8(12) (2018) 982.
[21] R. Calle-Gil, E. Castillo-Martinez, J. Carretero-Gonzilez, Cellulose Nanocrystals in Sustainable Energy Systems, Advanced Sustainable Systems 6(4) (2022) 2100395.
[22] A. Mukhopadhyay, Z. Cheng, A. Natan, Y. Ma, Y. Yang, D. Cao, W. Wang, H. Zhu, Stable and highly ion-selective membrane made from cellulose nanocrystals for aqueous redox flow batteries, Nano Letters 19(12) (2019) 8979-8989.
[23] Y. H. Lee, J. Y. Seo, C. D. Lee, J. H. Kim, S. W. Kim, W. J. Youe, J. G. Gwon, S. Y. Lee, Enabling Sustainable Lithium Metal Electrodes via Cholesteric Liquid Crystalline Cellulose Nanocrystal Nanomembranes, Advanced Energy Materials 12(28) (2022) 2200799.
[24] R. Goncalves, E. Lizundia, M. M. Silva, C. M. Costa, S. Lanceros-Mendez, Mesoporous cellulose nanocrystal membranes as battery separators for environmentally safer lithium-ion batteries, ACS Applied Energy Materials 2(5) (2019) 3749-3761.
[25] J. Wang, D. J. Gardner, N. M. Stark, D. W. Bousfield, M. Tajvidi, Z. Cai, Moisture and oxygen barrier properties of cellulose nanomaterial-based films, ACS Sustainable Chemistry & Engineering 6(1) (2018) 49-70.
[26] L. Wang, P. V. Kelly, N. Ozveren, X. Zhang, M. Korey, C. Chen, K. Li, S. Bhandari, H. Tekinalp, X. Zhao, Multifunctional polymer composite coatings and adhesives by incorporating cellulose nanomaterials, Matter (2022).
[27] C. Yang, Q. Wu, W. Xie, X. Zhang, A. Brozena, J. Zheng, M. N. Garaga, B. H. Ko, Y. Mao, S. He, Copper-coordinated cellulose ion conductors for solid-state batteries, Nature 598(7882) (2021) 590-596.
[28] A. Liu, S. Li, Z. Jiang, J. Du, Y. Tao, J. Lu, Y. Cheng, H. Wang, A renewable membrane with high ionic conductivity and thermal stability for Li-ion batteries, Journal of Power Sources 521 (2022) 230947.
[29] J. Gong, J. Li, J. Xu, Z. Xiang, L. Mo, Research on cellulose nanocrystals produced from cellulose sources with various polymorphs, RSC advances 7(53) (2017) 33486-33493.
[30] Y. Wang, J. He, D. Cao, E. Cakmak, X. Zhao, Q. Wu, Y. Zhao, H. Ren, X. Sun, Y. Li, Opening twisted polymer chains for simultaneously high printability and battery fast-charge, Energy Storage Materials 55 (2023) 42-54.
[31] Y. Wang, Y. Zhang, D. Cao, T. Ji, H. Ren, G. Wang, Q. Wu, H. Zhu, Designing Low Tortuosity Electrodes through Pattern Optimization for Fast-Charging, Small Methods 7(4) (2023) 2201344.
[32] Z. Cheng, H. Ye, F. Cheng, H. Li, Y. Ma, Q. Zhang, A. Natan, A. Mukhopadhyay, Y. Jiao, Y. Li, Tuning chiral nematic pitch of bioresourced photonic films via coupling organic acid hydrolysis, Advanced Materials Interfaces 6(7) (2019) 1802010.
[33] Q. Li, Y. Yin, D. Cao, Y. Wang, P. Luan, X. Sun, W. Liang, H. Zhu, Photocatalytic rejuvenation enabled self-sanitizing, reusable, and biodegradable masks against COVID-19, ACS nano 15(7) (2021) 11992-12005.
[34] H. Zhong, M. Sun, Y. Li, J. He, J. Yang, L. Zhang, J. Solid State Electrochem. 2016, 20, 1;
[35] K. Soeda, M. Yamagata, M. Ishikawa, ECS Trans. 2015, 64, 13;
[36] M. Bichon, D. Sotta, N. Dupre, E. De Vito, A. Boulineau, W. Porcher, B. Lestriez, ACS Appl. Mater. Interfaces 2019, 11, 18331;
[37] L. Ibing, T. Gallasch, P. Schneider, P. Niehoff, A. Hintennach, M. Winter, F. M. Schappacher, J. Power Sources 2019, 423, 183;
[38] R. Demiryurek, N. Gurbuz, G. Hatipoglu, M. Er, H. Malkoc, O. Guleryuz, G. Uyar, D. Uzun, M. N. Ateq, Int. J. Energy Res. 2021, 45, 21182;
[39] S. N. Bryntesen, I. Tolstorebrov, A. M. Svensson, P. Shearing, J. J. Lamb, O. S. Burheim, Mater. Adv. 2023, 4, 523.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

1. A method for making a water-stable electrode, said method comprising:
combining a mixture of a hybrid binder comprising cellulose nanofibers (CNF) and cellulose nanocrystals (CNC), active materials, and conductive material into an evenly mixed slurry in a solvent; and drying the slurry to form an electrode.

2. The method of claim 1, wherein the active materials comprise lithium, nickel, cobalt, manganese, oxygen, or any combination thereof.

3. The method of claim 2, wherein the active materials are in a single crystal in a ratio of LiNi_{1-x-y}CoₓMn_{y}O₂.

4. The method of claim 3, wherein the single crystal is LiNi_{0.8}Co_{0.1}Mn_{0.1}O₂ (NMC 811).

5. The method of claim 1, wherein the active materials, conductive material, and hybrid binder are combined such that the active materials comprise the largest weight percentage, the conductive material comprises the second largest weight percentage, and the hybrid binder comprises the third largest weight percentage.

6. The method of claim 1, wherein the conductive material is carbon black.

7. The method of claim 6, wherein the hybrid binder is dissolved in the solvent before being combined with the active materials and the carbon black.

8. The method of claim 1, wherein the hybrid binder comprises a mass ratio of CNC to CNF of about 10:90 to about 90:10.

9. The method of claim 1, wherein the solvent is water.

10. A water-stable electrode comprising a hybrid binder comprising a mixture of cellulose nanofibers (CNF) and cellulose nanocrystals (CNC), active materials, and conductive material.

11. The electrode of claim 10, wherein the active materials comprise lithium, nickel, cobalt, manganese, oxygen, or any combination thereof.

12. The electrode of claim 11, wherein the active materials are in a single crystal in a ratio of LiNi_{1-x-y}CoₓMn_{y}O₂.

13. The electrode of claim 12, wherein the single crystal is LiNi_{0.8}Co_{0.1}Mn_{0.1}O₂ (NMC 811).

14. The electrode of claim 10, wherein the hybrid binder comprises a mass ratio of CNC to CNF of about 10:90 to about 90:10.

15. The electrode of claim 10, wherein the hybrid binder prevents delithiation of the active materials in water.

16. The electrode of claim 10, wherein the hybrid binder captures water molecules, conducts lithium ions, or captures water molecules and conducts lithium ions.

17. The electrode of claim 10, wherein the electrode exhibits an initial coulombic efficiency of at least 80%.

18. The electrode of claim 10, wherein the conductive material is carbon black.

19. A battery comprising a cathode, an anode, an electrolyte, and a current collector, wherein at least the cathode is the water-stable electrode of claim 10.

20. The battery of claim 19, wherein:
(a) the active materials of the water-stable electrode comprise a single crystal of LiNi_{0.8}Co_{0.1}Mn_{0.1}O₂ (NMC 811);
(b) the hybrid binder of the water-stable electrode comprises a mass ratio of CNC to CNF of about 10:90 to about 90:10; or
(c) both (a) and (b).

21. (canceled)

22. (canceled)

23. (canceled)

24. (canceled)

25. (canceled)

26. (canceled)

27. (canceled)

28. (canceled)

29. (canceled)

30. (canceled)
